(19) United States
(12) Patent Application Publication
(10) Pub. No.: US 2008/0298021 A1
(43) Pub. Date: Dec. 4, 2008

(54) Notebook computer with hybrid diamond heat spreader

(76) Inventors: Ihab A. Ali, Santa Clara, CA (US); Frank F. Liang, San Jose, CA (US); Amaury Heresztyn, Mountain View, CA (US)

Correspondence Address: PVF -- APPLE INC.;c/o PARK, VAUGHAN & FLEMING LLP, 2820 FIFTH STREET, DAVIS, CA, 95618-7759, US

(21) Appl. No.: 11/809,460

(22) Filed: May 31, 2007

(51) Int. Cl. H05K 7/20

(52) U.S. Cl. 361/705; 361/687; 361/701; 361/708

(57) ABSTRACT

Embodiments of a device are described. This device includes an integrated circuit and a heat spreader coupled to the integrated circuit. This heat spreader includes a first layer of an allotrope of carbon. Note that the allotrope of carbon has an approximately face-centered-cubic crystal structure. Furthermore, the allotrope of carbon has a thermal conductivity greater than a first pre-determined value and a specific heat greater than a second pre-determined value.

### BACKGROUND

1. Field of the Invention

The present invention relates to heat-transfer techniques. More specifically, the present invention relates to the use of a diamond heat spreader to transport heat in computer systems.

2. Related Art

The computational performance of electronic devices has increased significantly in recent years. This increased performance has been accompanied by an increase in power consumption and associated heat generation. Furthermore, this additional heat generation has made it harder to maintain acceptable internal and external operational temperatures in these devices.

Portable devices, such as laptop computers (notebook PCs), cellular telephones, and personal digital assistants have additional design constraints which make it even harder to manage thermal load. In particular, size and weight limitations in such devices can make it difficult to achieve desired operational temperatures. For example, in many portable devices the size and weight of metal heat sinks may be prohibitive. Furthermore, battery life constraints in such devices may limit the available power for active cooling mechanisms, such as fans.

Hence what is needed are cooling mechanisms that overcome the problems listed above.

### SUMMARY

One embodiment of the present invention provides a device that includes an integrated circuit that is coupled to a heat spreader. This heat spreader includes a first layer of an allotrope of carbon. Note that the allotrope of carbon has an approximately face-centered-cubic crystal structure, which has a thermal conductivity greater than a first pre-determined value and a specific heat greater than a second pre-determined value.

In some embodiments, the allotrope of carbon includes diamond. Furthermore, in some embodiments the diamond is polycrystalline. Note that the diamond may be produced using chemical vapor deposition.

In some embodiments, the first layer includes grains of metal. For example, the metal may include aluminum and/or copper.

In some embodiments, the integrated circuit includes a processor.

In some embodiments, the first pre-determined value facilitates the transfer of steady-state heat from the integrated circuit, and the second pre-determined value facilitates the transfer of transient heat from the integrated circuit.

In some embodiments, the integrated circuit is coupled to the heat spreader using a thermal-interface material. This thermal-interface material may include: solder, thermal grease, and/or a phase-change material. However, in other embodiments the thermal-interface material includes a metal layer, such as: titanium, platinum, and/or gold.

In some embodiments, the device further includes a heat exchanger that is coupled to the heat spreader. Note that the heat exchanger may be configured to passively or actively transfer heat from the integrated circuit. For example, the heat exchanger may include a forced-fluid driver and a heat-coupling-mechanism coupled to the forced-fluid driver. This forced-fluid driver may be configured to pump heat.

Furthermore, in some embodiments the heat-coupling mechanism includes convective-cooling fins. These convective-cooling fins may include a second layer that includes the allotrope of carbon.

Another embodiment provides a computer system that includes the integrated circuit and the heat spreader coupled to the integrated circuit.

### BRIEF DESCRIPTION OF THE FIGURES

FIG. 1A is a block diagram illustrating a computer system in accordance with an embodiment of the present invention.

FIG. 1B is a block diagram illustrating a computer system in accordance with an embodiment of the present invention.

FIG. 2A is a block diagram illustrating a computer system in accordance with an embodiment of the present invention.

FIG. 2B is a block diagram illustrating a computer system in accordance with an embodiment of the present invention.

FIG. 3A is a block diagram illustrating a cooling mechanism in accordance with an embodiment of the present invention.

FIG. 3B is a block diagram illustrating a cooling mechanism in accordance with an embodiment of the present invention.

FIG. 4 is a block diagram illustrating a fin stack in accordance with an embodiment of the present invention.

Note that like reference numerals refer to corresponding parts throughout the drawings.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not intended to be limited to the embodiments shown, but is to be accorded the widest scope consistent with the principles and features disclosed herein.

Embodiments of a cooling mechanism, a device, and a computer system (such as a desktop computer and/or a laptop or portable computer) that includes the cooling mechanism and/or the device are described. Note that the computer system may include stationary and/or portable electronic devices, such as cellular telephones, personal digital assistants, game consoles, and MP3 players. This cooling mechanism may include a heat spreader that includes an allotrope of carbon (such as single-crystal or polycrystalline diamond). For example, the allotrope of carbon may have an approximately face-centered-cubic crystal structure. In addition, the allotrope of carbon may have a thermal conductivity greater than 1000 W/mK at room temperature and a specific heat greater than 250 J/kgK at room temperature.

In some embodiments, the cooling mechanism is coupled to one or more integrated circuits (such as a processor, a graphics processor, and/or an application-specific integrated circuit) in the device and/or the computer system, for example, using a thermal-interface material, such as: solder, thermal grease, a metal, and/or a phase-change material. Furthermore, the thermal conductivity of the heat spreader may facilitate transfer of steady-state heat from the integrated circuit, and the specific heat may facilitate transfer of transient heat from the integrated circuit.

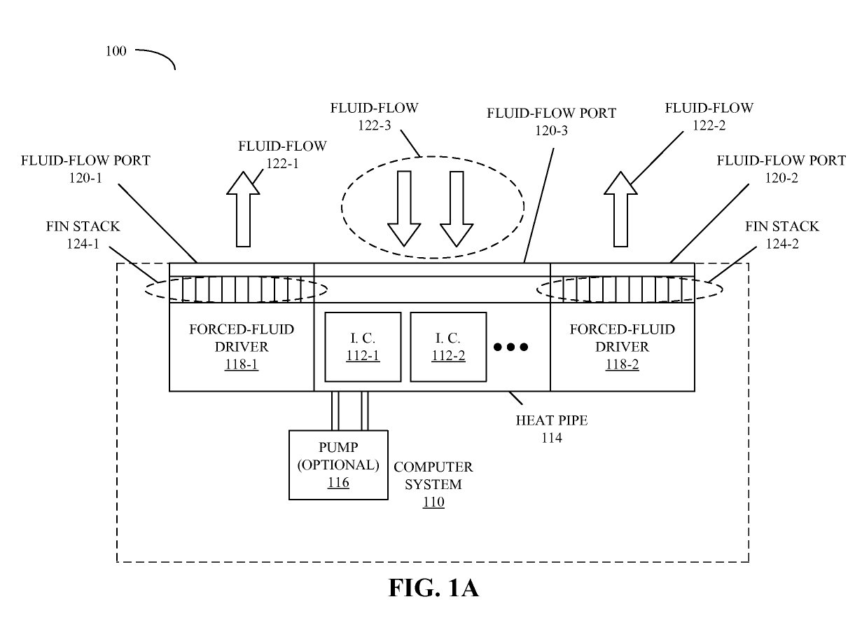

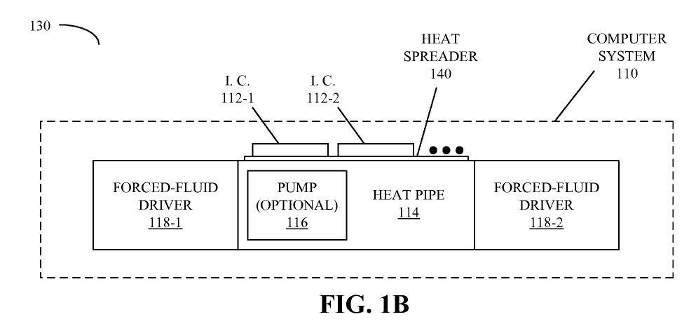

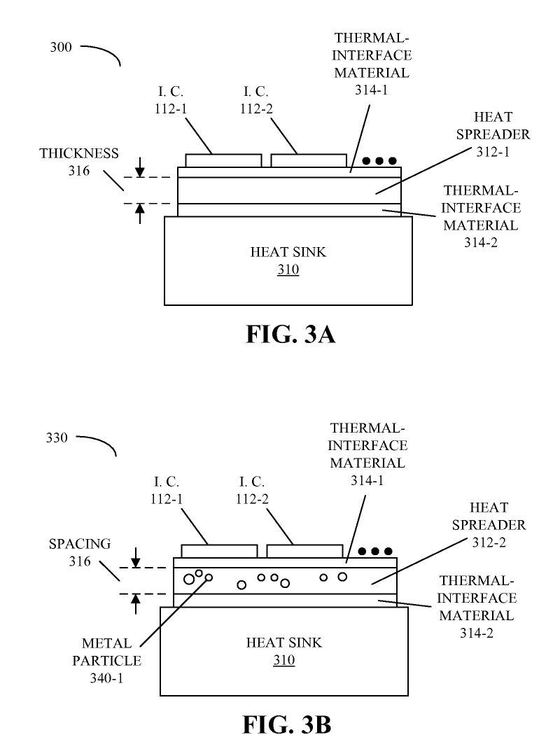

We now describe embodiments of the cooling mechanism, the device, and the computer system. FIGS. 1A and 1B present block diagrams illustrating embodiment 100 (top view) and 130 (side view) of computer system 110 (such as a laptop computer). This computer system may include one or more integrated circuits or IC.s 112 (such as a processor, a graphics processor, and/or an application-specific integrated circuit) that generate heat during operation. These integrated circuits 112 are thermally coupled to a heat pipe 114. For example, the integrated circuits 112 may be coupled to an external surface of the heat pipe 114 via a heat spreader 140 (which is discussed further below with reference to FIGS. 3A and 3B).

In an exemplary embodiment, the heat pipe 114 has a solid copper jacket with a hollow interior. In some embodiments, an inner surface of the jacket may be coated with a thin-wick structure that includes copper powder to increase an effective contact area. In addition, the hollow interior may hold a soft vacuum, i.e., may have reduced air pressure. This reduced pressure may allow water to boil more easily during operation of the computer system 110. The resulting water vapor may be very effective in carrying heat from the integrated circuits 112 to forced fluid drivers 118 (such as fans) that are located at opposite ends of the heat pipe 114. Consequently, the hollow interior of the heat pipe 114 may have an effective thermal conductivity of 5000 W/m/C, which is 100 times larger than that of solid copper.

However, in other embodiments the interior of the heat pipe 114 includes a liquid coolant (i.e., a material with little or no sheer strength). For example, the liquid coolant may include: water, a coolant in an R133 group of coolants, and/or a coolant in an R134 group of coolants. Note that the heat pipe 114 may include two or more metal castings. These castings may include portions of a tube or channel. When the castings are combined, the tube or channel may be formed, thereby providing a path for the liquid coolant. Moreover, in some embodiments these castings may be soldered or welded to each other, thereby hermetically sealing the tube or channel.

Furthermore, in some embodiments an optional pump 116 coupled to the heat pipe 114 circulates the liquid coolant, thereby facilitating heat transfer from a power source in the computer system 110 (such as one of the integrated circuits 112) to the forced-fluid drivers 118.

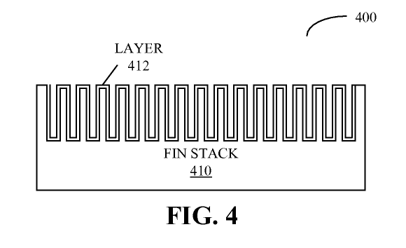

These forced-fluid drivers may circulate a fluid (for example, a gas such as air) via fluid-flow ports 120 (such as vents), i.e., the forced-fluid drivers 118 may drive fluid flows 122. This fluid flow may transfer heat from an interior of the computer system 110 to an external environment. Note that in some embodiments such heat transfer is enhanced by using a heat-coupling mechanism, such as convective-cooling fins. For example, the computer system 110 may include fin stacks 124 (which are discussed further below with reference to FIG. 4). Furthermore, in some embodiments the fluid flows 122 include a liquid, i.e., alternate forced-fluid drivers 118 are used.

Note that the heat pipe 114 may be a very efficient, passive or active heat-transfer mechanism. In particular, a thermal gradient across the heat pipe 114 may be less than 2 C. Thus, the heat pipe 114 may maintain a temperature inside of the computers system 1O and/or on an outer surface of the computer system 110.

In some embodiments, the fluid-flow ports 122 are tapered such that a cross-sectional area decreases as fluid flows from inside of the computer system 110 to outside. For example, the fluid-flow ports 122 may constitute a Venturi tube. Note that this decrease in area may give rise to a Bernoulli effect in which a partial vacuum at the output of the fluid-flow ports 120-1 and 120-2 (and at the input to fluid-flow port 120-3) reduces and/or eliminates recirculation of the fluid flows 122, thereby reducing the temperature inside of the computer system 110.

Furthermore, in some embodiments the optional pump 116 includes a mechanical pump and/or an electrostatic pump. Alternatively, in some embodiments the pump 116 is configured to circulate the liquid coolant using mechanical vibration (for example, using ultrasonic frequencies) of a membrane.

Note that in some embodiments the computer system 110 (as well as the embodiments discussed below) includes fewer or additional components, two or more components are combined into a single component, and/or a position of one or more components may be changed. For example, in some embodiments there may be more or fewer forced fluid drivers 118 and/or a direction of the fluid flows 122 may be reversed. Furthermore, in some embodiments the liquid coolant includes a refrigerant.

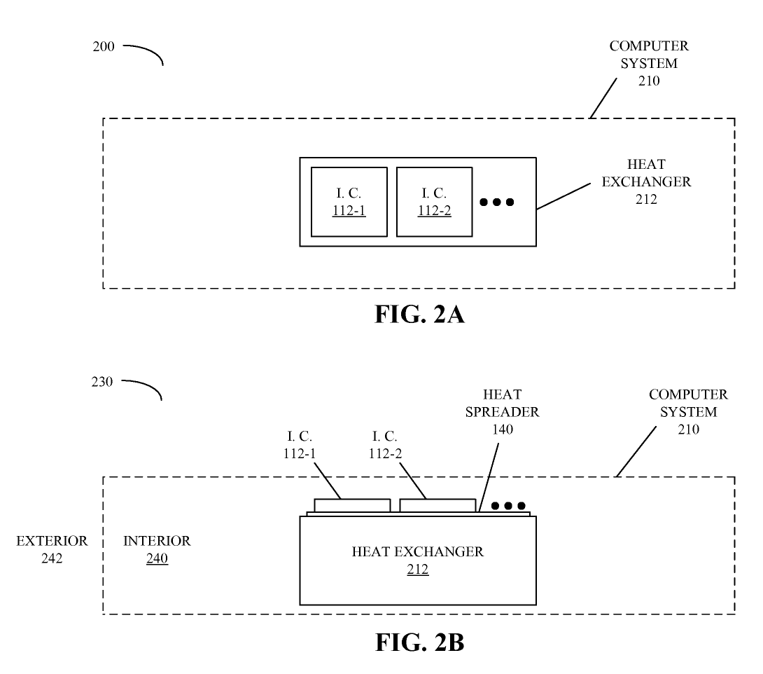

While computer system 110 includes active heat-transfer mechanisms, such as forced-fluid drivers 118 and/or the optional pump 116, in other embodiments (such as in devices having low power consumption) passive cooling techniques are used. This is shown in FIGS. 2A and 2B, which present block diagrams illustrating embodiments 200 (top view) and 230 (side view) of computer system 210. In this computer system, one or more integrated circuits 112 are thermally coupled to a passive heat exchanger 212 using heat spreader 140. This heat exchanger transfers heat generated by a power source in the one or more integrated circuits 112 from an interior 240 of the computer system 210 to an external environment or exterior 242.

We now discuss embodiments of the heat spreader. FIG. 3A presents a block diagram illustrating an embodiment of a cooling mechanism 300. In this cooling mechanism, one or more integrated circuits 112 are coupled to a heat sink 310 (such as heat pipe 114 in FIGS. 1A and 1B or heat exchanger 212 in FIGS. 2A and 2B) by a heat spreader 312-1.

In some embodiments, the heat spreader 312-1 includes an allotrope of carbon having an approximately face-centered-cubic crystal structure, such as single-crystal or polycrystalline diamond. This diamond may be produced using chemical vapor deposition (or another fabrication or manufacturing process). In addition to the physical properties discussed previously (including the thermal conductivity and the heat capacity), the heat spreader 312-1 may also have a good match to the thermal-expansion coefficients of the one or more integrated circuits 112 and/or the heat sink 310. Furthermore, the heat spreader 312-1 may have a high strength or stiffness value. In an exemplary embodiment the heat spreader 312-1 is a thin film that has a thickness 316 between 1 and 50 μm. In some embodiments, the heat spreader 312-1 has isotropic thermal properties.

In exemplary embodiments, the heat spreader 312 includes: a film that includes a hybrid of diamond and copper with a coefficient of thermal expansion of 3-8 ppm/K, a density of 4 g/cm³, and a thermal conductivity of 400 W/mK; a film that includes a hybrid of diamond and aluminum with a coefficient of thermal expansion of 5-9 ppm/K, a density of 3 g/cm³, and a thermal conductivity of 650 W/mK; a diamond film with a coefficient of thermal expansion of 1-2 ppm/K, a density of 3.5 g/cm³, and a thermal conductivity of 1000-2000 W/mK; an aluminum film with a coefficient of thermal expansion of 23 ppm/K, a density of 2.7 g/cm³, and a thermal conductivity of 200 W/mK; and/or a copper film with a coefficient of thermal expansion of 17 ppm/K, a density of 9 g/cm³, and a thermal conductivity of 385 W/mK. Note that at room temperature the specific heat of copper is 0.4 J/gK, the specific heat of aluminum of 0.9 J/gK, and the specific heat of diamond is 0.5 J/gK.

Note that the heat spreader 312-1 is sandwiched between one or more conformal and/or insulating layers, such as thermal-interface materials 314. Note that one or both surfaces of the heat spreader 312-1 may be metallized with an over coats (for example, with titanium, platinum, and/or aluminum) to facilitate soldering to either or both of the thermal-interface materials 314.

In an exemplary embodiment, thermal-interface material 314-1 includes: solder (for example, a low melting-point solder), thermal grease, and/or a phase-change material (such as epoxy). Furthermore, thermal-interface material 314-2 may include a metal, such as: titanium, platinum, and/or gold. Note that a reflowed solder (such as one including copper) may be used to thermally couple thermal-interface material 314-2 to the heat spreader 312-1 and/or the heat sink 310.

Moreover, in some embodiments the heat spreader 312-2 is a heterogeneous or hybrid material. For example, the heat spreader 312-2 may include diamond and metal grains (such as aluminum and/or copper). This is shown in FIG. 3B, which presents a block diagram illustrating an embodiment of a cooling mechanism 330 in which the heat spreader 312-2 includes metal particles 340 (which may have different cross-sectional areas).

By including one of the heat spreaders 312 (such as diamond), devices and computer systems (such as computer system 110 in FIGS. 1A and 1B and computer system 210 in FIGS. 2A and 2B) may be able to accommodate spikes in heat generated by the one or more integrated circuits 112. For example, a micro-processor with a 31 W thermal-design power may have an average junction temperature of 90 C. However, because of thermal spikes (associated with time-varying operation and/or power-supply fluctuations) the standard deviation in the junction temperature may be ±15 C. Such large variations may degrade or reduce the operational life and/or reliability of the micro-processor. With one of the heat spreaders 312, the average junction temperature and the standard deviation in the junction temperature are reduced, thereby increasing the operational life and reliability of the integrated circuits 112 (such as micro-processors).

In an exemplary embodiment, the temperature and fluctuation magnitude of a silicon junction (subjected to repeated cycles of thermal-design power for 3.4 s and idle for 1.6 s) was reduced by around 4 C using heat spreaders 312 that include a hybrid of diamond and aluminum or copper and aluminum. In another exemplary embodiment, the temperature and fluctuation magnitude of a silicon junction (subjected to repeated cycles of thermal-design power for 3.4 s and idle for 1.6 s) was reduced by around 2 C using a thin (10-100 μm) diamond film deposited on a copper heat spreader.

Improved materials, such as diamond, may be included in other heat-transfer components. This is shown in FIG. 4, which presents a block diagram illustrating an embodiment 400 of a fin stack 410 (such as fin stack 124 in FIGS. 1A and 1B). This fin stack includes a layer 412 that includes the allotrope of carbon, such as single-crystal or polycrystalline diamond. Layer 412 may reduce the thermal resistance between the fin stack 410 and the fluid in fluid flows 122 (FIGS. 1A and 1B), thereby facilitating heat transfer between devices and/or computer systems (such as computer system 110 in FIGS. 1A and 1B) and the external environment.

The foregoing descriptions of embodiments of the present invention have been presented for purposes of illustration and description only. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A device, comprising:
an integrated circuit; and
a heat spreader coupled to the integrated circuit, wherein the heat spreader includes a first layer;
wherein the first layer includes an allotrope of carbon;
wherein the allotrope of carbon has an approximately face-centered-cubic crystal structure, and
wherein the allotrope of carbon has a thermal conductivity greater than a first pre-determined value and a specific heat greater than a second pre-determined value.

2. The device of claim 1, wherein the allotrope of carbon includes diamond.

3. The device of claim 2, wherein the diamond is polycrystalline.

4. The device of claim 2, wherein the diamond is produced using chemical vapor deposition.

5. The device of claim 1, wherein the first pre-determined value is 1000 W/mK at room temperature.

6. The device of claim 1, wherein the second predetermined value is 250 J/kgK at room temperature.

7. The device of claim 1, wherein the first layer includes grains of metal.

8. The device of claim 7, wherein the metal includes aluminum or copper.

9. The device of claim 1, wherein the integrated circuit includes a processor.

10. The device of claim 1, wherein the first pre-determined value facilitates transfer of steady-state heat from the integrated circuit, and wherein the second pre-determined value facilitates transfer of transient heat from the integrated circuit.

11. The device of claim 1, wherein the integrated circuit is coupled to the heat spreader using a thermal-interface material.

12. The device of claim 12, wherein the thermal-interface material includes solder, thermal grease, or a phase-change material.

13. The device of claim 12, wherein the thermal-interface material includes a metal layer.

14. The device of claim 13, wherein the metal layer includes titanium, platinum, or gold.

15. The device of claim 1, wherein the first layer has a thickness between 1 and 50 μm.

16. The device of claim 1, further comprising a heat exchanger, wherein the heat spreader is coupled to the heat exchanger.

17. The device of claim 16, wherein the heat exchanger is configured to passively transfer heat from the integrated circuit.

18. The device of claim 16, wherein the heat exchanger is configured to actively transfer heat from the integrated circuit.

19. The device of claim 16, wherein the heat exchanger includes:
a forced-fluid driver, wherein the forced-fluid driver is configured to pump heat; and
a heat-coupling-mechanism coupled to the forced-fluid driver.

20. The device of claim 19, wherein the heat-coupling mechanism includes convective-cooling fins.

21. The device of claim 20, wherein at least some of the convective-cooling fins include a second layer, and wherein the second layer includes the allotrope of carbon.

22. A computer system, comprising:
an integrated circuit; and
a heat spreader coupled to the integrated circuit, wherein the heat spreader includes a first layer;
wherein the first layer includes an allotrope of carbon;
wherein the allotrope of carbon has an approximately face-centered-cubic crystal structure, and
wherein the allotrope of carbon has a thermal conductivity greater than a first pre-determined value and a specific heat greater than a second pre-determined value.
